(19) United States
(12) Patent Application Publication
(10) Pub. No.: US 2006/0006798 A1
(43) Pub. Date: Jan. 12, 2006

(54) Passivation layer

(75) Inventor: Alastair Robert Buckley, Edinburgh (GB)

Correspondence Address: Howson and Howson;Spring House Corporate Center, P O Box 457, Spring House, PA, 19477, US

(73) Assignee: MicroEmissive Displays Limited, Edinburg (GB)

(21) Appl. No.: 10/528,725

(22) PCT Filed: Sep. 30, 2003
(86) PCT No.: PCT/GB03/04247

§ 371 Date: Mar. 22, 2005

(30) Foreign Application Priority Data
Sep. 30, 2002 (GB) 022649.6

(51) Int. Cl. H05B 33/04; H05B 33/14; H05B 33/10

(52) U.S. Cl. 313/512; 313/509; 313/506

(57) ABSTRACT

An organic light emitting diode device comprises a substrate (1), a layer (3) of organic, preferably polymeric, light emitting material, and a transparent cathode (4) comprising a layer of material with a work function less than 4 eV. The device has a passivation layer (5) comprising boron oxide.

### BACKGROUND OF THE INVENTION

The present invention relates to an organic light emitting diode (OLED) device, a method of manufacturing an OLED device and a passivation layer for an electronic device.

In particular, the OLED may be a polymer light emitting diode (PLED). PLEDs are usually fabricated on a conductive substrate such as of indium tin oxide (ITO) forming a transparent anode on to which layers of transparent conducting polymer, light emitting polymer, and cathode layers are deposited. A metal can, containing a getter to remove any water and oxygen, is glued over the device to encapsulate it.

Such a “bottom-emitting” device is expensive and slow to manufacture and is bulky.

Accordingly, “top-emitting” devices are also known, in which the substrate is opaque, for example a silicon wafer comprising active circuitry. In such devices, the light is emitted through the cathode, which must have very good electrical conductivity and transparency. Advantageously the cathode comprises a layer of calcium, e.g. from 5 to 30 nm in thickness.

A major problem with such a device is that both the calcium and the light-emitting polymer are very reactive with oxygen and water. It is therefore known to deposit an encapsulating layer on to the layer of calcium to prevent the ingress of oxygen and water. A large number of possible materials for the encapsulating layer have been suggested. For example, US-A1-20010052752 suggests the use of a dielectric oxide selected from the group consisting of Al₂O₃, SiO₂, TiO₂, ZrO₂, MgO, HfO₂, Ta₂O₅, aluminum titanium oxide and tantalum hafnium oxide. Nitrides, such as silicon nitride, have also been proposed.

A serious disadvantage of all of these known materials is that the technique by which they are deposited tends to damage the calcium and/or the light emitting polymer. If the encapsulation material is deposited by electron beam evaporation, secondary electrons oxidize the light-emitting polymer. If the deposition method is sputtering, both secondary electron ionization and heavy ion damage tend to occur. If plasma enhanced chemical vapor deposition is used, radiofrequency electric fields permeate through the device and, permanently degrade its performance. US-A1-20010052752 therefore teaches the use of atomic layer epitaxy as the deposition method, but this is an expensive technique.

It is known to deposit a passivation layer to protect the calcium and light emitting polymer layers from the subsequent deposition of the encapsulating layer. For example, U.S. Pat. No. 5,739,545 describes zinc sulfide as a passivation material. However, the use of zinc sulfide has been found to reduce device lifetime by a factor of 10, possibly because the light-emitting polymer becomes contaminated with sulfur.

### SUMMARY OF THE INVENTION

It is an aim of the present invention to provide a practical and effective passivation layer in a top-emitting OLED.

Accordingly, the present invention provides an organic light emitting diode device having a passivation layer comprising boron oxide.

We have found that when deposited in a film of suitable thickness, boron oxide (B₂O₃) is effective in protecting the device from subsequent deposition techniques such as electron beam deposition and sputtering. Importantly, boron oxide can be thermally deposited. Thermal deposition does not cause damage to the sensitive light emitting polymer or calcium layers. Boron oxide also has a very low coefficient of thermal expansion (about 1 ppm/° C. at room temperature) so that the deposited film does not crack. This is unusual, since most inorganic salts that can be thermally deposited crack visibly on cooling. Boron oxide appears to have very few pinholes. Boron oxide films appear to be glassy and amorphous when thermally deposited, unlike most thermally deposited films, which are crystalline.

Preferably, the thickness of the passivation layer is from 50 nm to 1 μm, and the thickness can be adapted to the energy of the electrons, ions or fields from which protection is required.

Preferably, the device comprises a substrate, a layer of organic, preferably polymeric, light emitting material, and a transparent cathode comprising a layer of material with a work function less than 4 eV, e.g. calcium. Said passivation layer preferably overlies the layer of material with a work function less then 4 eV directly.

Preferably, the device comprises an encapsulating layer overlying said passivation layer. The encapsulating layer may comprise any suitable encapsulating material, for example a dielectric oxide selected from the group consisting of Al₂O₃, SiO₂, TiO₂, ZrO₂, MgO, HfO₂, Ta₂O₅, aluminum titanium oxide and tantalum hafnium oxide.

In a preferred embodiment, the device comprises sealing layers, such as of epoxy resin and glass.

The invention also provides a method of manufacturing an organic light emitting diode device comprising depositing a passivation layer comprising boron oxide on the device.

Preferably, said passivation layer is deposited by thermal evaporation.

Preferably, the device comprises a substrate, a layer of organic, preferably polymeric, light emitting material, and a transparent cathode comprising a layer of material with a work function less than 4 eV, e.g. calcium. Said passivation layer is preferably deposited directly on to the layer of material with a work function less than 4 eV.

In a preferred embodiment, the method comprises a further step of depositing an encapsulation layer on to the passivation layer. The encapsulation layer may comprise any suitable encapsulating material, for example a dielectric oxide selected from the group consisting of Al₂O₃, SiO₂, TiO₂, ZrO₂, MgO, HfO₂, Ta₂O₅, aluminum titanium oxide and tantalum hafnium oxide. Preferably, the encapsulation layer is deposited by electron beam evaporation, but it may alternatively be deposited by sputtering.

Preferably, the method comprises sealing the device, for example with epoxy resin and glass.

More generally, the invention provides a passivation layer for an electronic device, the passivation layer comprising boron oxide. As far as we are aware, boron oxide has never been suggested as a passivation material for any application.

### BRIEF DESCRIPTION OF THE DRAWINGS

A particular embodiment of the invention will now be described, by way of example only, with reference to the accompanying drawings, in which:

FIG. 1 is a schematic cross section of a device according to the invention; and

FIG. 2 shows the results of an experiment comparing degradation of silicon dioxide and boron oxide.

### DETAILED DESCRIPTION OF THE PREFERRED EMBODIMENT

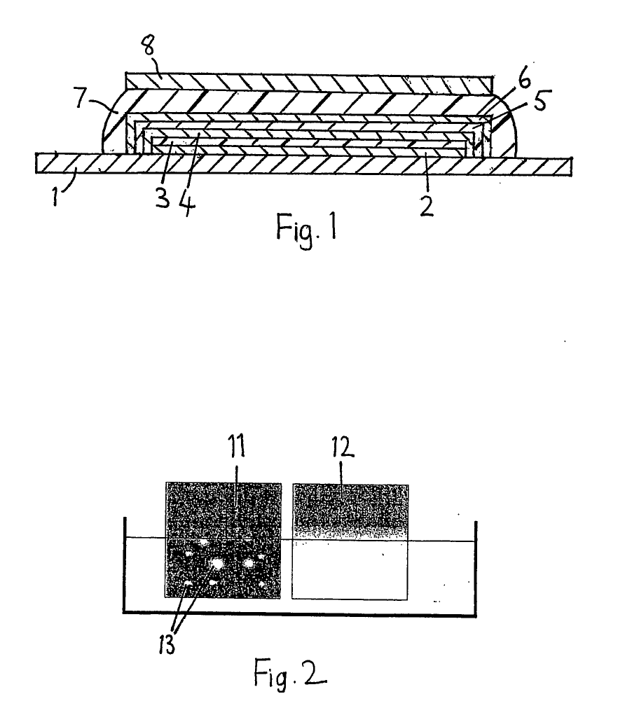

FIG. 1 shows a top-emitting PLED device comprising a silicon substrate 1, a nickel anode 2, a light emitting polymer layer 3 and a transparent calcium cathode layer 4.

A passivation layer 5 of boron oxide is deposited on the calcium layer 4 by thermal evaporation. This process comprises simply heating the boron oxide to evaporate it under a suitable vacuum and is the same process used for depositing the calcium layer 4. Boron oxide evaporates at about 1000° C. The thermal evaporation process does not damage the light emitting polymer layer 3 or the calcium layer 4.

The boron oxide layer 5 is “conformal”, i.e. continuous without pinholes. This is demonstrated by FIG. 2, which shows the results of an experiment comparing silicon dioxide and boron oxide layers. Two test devices 11, 12, each comprised a glass substrate coated with a thin film of calcium. The first device 11 was then coated with a layer of silicon dioxide whilst the second device 12 was coated with a layer of boron oxide. Both devices were submerged in water. In the first device 11, the calcium was degraded at pinholes 13. However, in the second device 12, the degradation was uniform, indicating a conformal film of boron oxide. (Boron oxide is slightly soluble in water and cannot therefore encapsulate on its own.)

Returning to FIG. 1, an encapsulation layer 6 is deposited by electron beam evaporation on the passivation layer 5. The encapsulation layer is of a suitable encapsulating material such as Al₂O₃, SiO₂, Ta₂O₅ or Si₃N₄.

The device is sealed by a layer of epoxy resin 7 deposited on the encapsulation layer 6, also covering the edges of device layers 2 to 6, and contacting the substrate 1. The device is completed by adding a glass plate 8.

All forms of the verb “to comprise” used in this specification have the meaning “to consist of or include”.

1. An organic light emitting diode device having a passivation layer comprising boron oxide.

2. A device according to claim 1, comprising a substrate, a layer of organic light emitting material, and a transparent cathode comprising a layer of material with a work function less than 4 eV.

3. A device according to claim 2, wherein said material with a work function of less than 4 eV comprises calcium.

4-8. (canceled)

9. A method of manufacturing an organic light emitting diode device, comprising depositing a passivation layer comprising boron oxide on the device.

10. A method according to claim 9, wherein said passivation layer is deposited by thermal evaporation.

11-18. (canceled)

19. A passivation layer for an electronic device, the passivation layer comprising boron oxide.

20. A device according to claim 2, wherein said light emitting material is a polymeric light emitting material.

21. A device according to claim 2, wherein said passivation layer directly overlies said layer of material with a work function less than 4 eV.

22. A device according to claim 1, further comprising an encapsulating layer overlying said passivation layer.

23. A device according to claim 22, wherein said encapsulating layer comprises a dielectric oxide selected from a group consisting of Al₂O₃, SiO₂, TiO₂, ZrO₂, MgO, HfO₂, Ta₂O₅, aluminum titanium oxide, and tantalum hafnium oxide.

24. A device according to claim 1, further comprising sealing layers of adhesive and glass.

25. A device according to claim 24, wherein said adhesive comprises epoxy resin.

26. A method according to claim 9, wherein the device comprises a substrate, a layer of organic light emitting material, and a transparent cathode comprising a layer of material with a work function less than 4 eV.

27. A method according to claim 26, wherein said passivation layer is deposited directly onto said layer of material with a work function less than 4 eV.

28. A method according to claim 9, further comprising a step of depositing an encapsulating layer onto said passivation layer.

29. A method according to claim 28, wherein said encapsulating layer comprises a dielectric oxide selected from a group consisting of Al₂O₃, SiO₂, TiO₂, ZrO₂, MgO, HfO₂, Ta₂O₅, aluminum titanium oxide, and tantalum hafnium oxide.

30. A method according to claim 28, wherein said encapsulating layer is deposited by electron beam evaporation.

31. A method according to claim 28, wherein said encapsulating layer is deposited by sputtering.

32. A method according to claim 9, further comprising the step of sealing the device with an adhesive and glass.

33. A method according to claim 9, comprising the step of adapting the thickness of said passivation layer to energy of electrons, ions, or fields from which protection is required.
